(19) United States
(12) Patent Application Publication
(10) Pub. No.: US 2010/0313758 A1
(43) Pub. Date: Dec. 16, 2010

(54) GAS ABSORPTION MEMBRANES AND THE MANUFACTURE THEREOF

(75) Inventors: Geoff Stevens, Williamstown (AU); Jilska Perera, Princes Hill (AU); Julianna Franco, Brooklyn (AU); Sandra Kentish, East Kew (AU)

Correspondence Address: MERCHANT & GOULD PC, P.O. BOX 2903, MINNEAPOLIS, MN, 55402-0903, US

(73) Assignee: CO2CRC TECHNOLOGIES PTY LTD., Kensington (AU)

(21) Appl. No.: 12/483,822

(22) Filed: Jun. 12, 2009

(51) Int. Cl. B01D 53/14; C23C 14/34; B01D 53/22

(52) U.S. Cl. 96/10; 96/11; 96/12; 204/192.15

(57) ABSTRACT

A membrane is used for separating carbon dioxide from a gas phase. The membrane includes a substrate having micro-pores that extend through the substrate and a thin hydrophobic coating on one side of the substrate in which the pores of the substrate are substantially unobstructed by the coating so that the gas phase can penetrate the pores. The coating opposes or substantially resists a liquid solvent for absorbing carbon dioxide from penetrating the pores of the membrane from the side having the coating. The membrane may also be used for separating carbon dioxide in a flue gas of a coal fired power station. Further, the coating may be relatively inert to the liquid solvent compared to the substrate.

### FIELD OF THE PRESENT INVENTION

The present invention relates to gas absorption membranes for separating carbon dioxide from gas streams such as flue gas streams of coal fired power stations and a process for the manufacture of the membranes. The gas absorption membranes may have a broad range of applications such as, but by no means limited to, separating carbon dioxide from natural gas and processing streams of cement, iron and other metal refining plants.

### BACKGROUND OF THE PRESENT INVENTION

The current technology which exists to separate carbon dioxide from flue gas involves chemical absorption in a packed column using an amine based solvent. The technology has been used in industry for over 50 years and has a number of disadvantages. One of the disadvantages of using a packed column for extracting carbon dioxide from the flue gas is the size of the column required. For instance, a typical 645MW coal fired power station produces a flue gas at a rate of 2×10⁶ m³/hr and contains approximately 12% vol CO₂. In order to extract the carbon dioxide using a conventional packed column would require a packed column of approximately 3000 m³.

It is an object of the present invention to provide an alternative technology to the conventional packed column by devising a gas absorption membrane for separating carbon dioxide from gas streams containing carbon dioxide and other gases.

### SUMMARY OF THE PRESENT INVENTION

It may be said that the present invention resides in a membrane for separating carbon dioxide from a gas phase, the membrane comprising:

a) a substrate having micro-pores that extend through the substrate; and

b) a thin hydrophobic coating on one side of the substrate in which the pores of the substrate are substantially unobstructed by the coating so that the gas phase can penetrate the pores, and the coating opposes or substantially resists a liquid solvent for absorbing carbon dioxide, from penetrating the pores of the membrane from the side having the coating.

It may also be said that the present invention resides in a membrane for separating carbon dioxide in a flue gas of a coal fired power station, the membrane comprising:

a) a substrate having micro-pores that extend through the substrate to allow the gas phase to penetrate into the substrate; and

b) a thin coating on at least one side of the substrate such that the pores are substantially unobstructed by the coating, and when in use, the gas phase penetrates the pores of the substrate, and a liquid solvent in contact with the coating is substantially resisted from penetrating the pores, and wherein carbon dioxide in the pores of the substrate is transferred to the liquid solvent.

In an embodiment, the coating is relatively inert to the liquid solvent compared to the substrate. Suitably, the coating is a hydrophobic coating that opposes or resists an aqueous solvent from penetrating the pores of the substrate from the side having the coating.

It may also be said that the present invention resides in a membrane for separating carbon dioxide from a gas phase, the membrane comprising:

a) a hollow fibre substrate having micro-pores that extend from an internal lumen of the substrate to an outer face of the substrate; and

b) a thin hydrophobic coating on either one or a combination of inner and outer surfaces of the substrate, wherein the pores of the substrate are substantially unobstructed by the coating so that the gas phase can penetrate the pores and the coating opposes or substantially resists a liquid solvent for absorbing carbon dioxide, from penetrating the pores of the membrane from the side having the coating.

It may also be said that the present invention resides in a membrane for separating carbon dioxide from a gas phase, the membrane comprising:

a) a hollow fibre substrate having micro-pores that extend from an internal lumen of the substrate to an outer face of the substrate; and

b) a thin hydrophobic coating on either one or a combination of inner and outer surfaces of the substrate, wherein the pores of the substrate are substantially unobstructed by the coating and when in use, a liquid solvent is conveyed in the lumen of the membrane and the gas phase on the outside of the membrane.

It may also be said that the present invention resides in a membrane that can be used in the mass transfer of a targeted substance between a non-aqueous phase and an aqueous phase, the membrane comprising:

a) a substrate having micro-pores that extend through the substrate; and

b) a thin hydrophobic coating on one side of the substrate in which the pores of the substrate are substantially unobstructed by the coating so that the non-aqueous phase can penetrate the pores, and the coating opposes or substantially resists the aqueous phase from penetrating the pores of the membrane from the side having the coating, and thereby facilitating transfer of the targeted substance between the aqueous and non-aqueous phases.

In an embodiment, the non-aqueous phase is a vapour phase or gas stream. For instance, the non-aqueous phase is a gas stream containing targeted substance in the form of carbon dioxide and the aqueous stream is a liquid solvent having an affinity for carbon dioxide. In other words, the gas stream containing carbon dioxide can enter the pores and the liquid solvent in contact with the coating is substantially resisted from entering the pores.

### BRIEF DESCRIPTION OF THE DRAWINGS

Embodiments of the present invention will now be described with reference to the following drawings.

FIG. 1 is a schematic cross sectional view of membrane having micro-pores in which the gas phase including carbon dioxide can penetrate, wherein a gas phase is conveyed on one side of the membrane and a solvent for absorbing carbon dioxide is conveyed on an opposite side which has a thin coating which not shown in FIG. 1;

FIG. 2 is a schematic perspective view of a hollow fibre membrane having a internal lumen in which the liquid solvent is conveyed for absorption of carbon dioxide from a gas phase which is conveyed on the outside of the membrane, optionally, the gas phase may be conveyed in the lumen and the solvent on the outside;

FIG. 3 is a schematic illustration of a plasma reactor for coating a face of the membrane with a thin coating that is substantially inert to the solvent;

FIGS. 4a to 4f are a set of photographs of a scanning electron microscope (SEM) of which FIGS. 4a and 4b are photos of a control polypropylene (PP) membrane before use and after 25 days of contact with a 20 wt % MEA solution respectively, FIGS. 4c and 4d are photos of a polytetrafluoroethylene (PTFE) membrane before use and after 25 days of contact with a 20 wt % MEA solution respectively, and FIGS. 4e and 4f are photos of a treated polypropylene (PTPP) membrane according to an embodiment of the invention before use and after 25 days of contact with a 20 wt % MEA (monoethanolamine) solution respectively, wherein magnification of the photos is at 5000×;

FIG. 5 is a graph illustrating the wetting energy of the control polypropylene (PP), polytetrafluoroethylene (PTFE), treated polypropylene (PTPP) as a product of the surface tension and cosine of contact angle versus surface tension and MEA concentration;

FIGS. 6a and 6b are SEM photos of the outside of an untreated PP hollow fibre membrane that have been used and unused respectively, and FIGS. 6c and 6d are SEM photos of the outside of a plasma treated PTPP hollow fibre membrane that have been used and unused respectively, wherein the photos are at a magnification of 1000×;

FIGS. 7a and 7c are SEM photos of the inside of an untreated PP hollow fibre membrane that have been used and unused respectively, and FIGS. 7c and 7d are SEM photos of the inside of a plasma treated PTPP hollow fibre membrane that have been used and unused respectively, wherein the photos are at a magnification of 2000×;

FIG. 8a illustrates changes in CO₂ flux for PP and PTPP tubular membrane cartridges with liquid flow at various concentrations on the outside of the tubes (shell side) and gas flowing in lumens;

FIG. 8b illustrates changes in CO₂ flux for PP and PTPP hollow fibre membranes for the same configuration with MEA solution at various flowrates; and

FIG. 9 is a graph illustrating a comparison of the carbon dioxide transferred (i.e., CO₂ flux) using an 20 wt % MEA solution at time 0 hours, 22 hours and 46 hours, wherein the broken line represents the flux for PTPP, the bold unbroken line represents the flux for untreated PP and the unbroken line represents the flux for PTFE.

### DETAILED DESCRIPTION

Throughout this specification the terms solvent, liquid solvent or absorbent have been used interchangeably and embrace any solvent having an affinity for carbon dioxide. Although amine solvents are a type of solvent that is likely to be useful and are referred to a number of times in this specification, any aqueous solution may be used. For example, it is within the scope of the present invention that the solvent may include, but is by no means limited to, solutions in which the activate absorbent is a nitrogen containing compound such as amino acids, ammonia containing solutions and amine solutions; and alkali carbonates such as potassium carbonate and sodium carbonate.

The substrate may be any polymeric material including thermoplastics and thermoset plastics.

The polymeric material may be also be a homo or co-polymer and may even be a combination of, or even a lamination of any polymeric material including organic based polymers such as cellulose acetates, polyacrylates, polyamides, polyesters, polycarbonates, polyimides and polystyrenes. Suitably, the polymeric material includes polyolefin having at least two carbon atoms in each repeating unit and optionally, as high as 9 or 10 carbon atoms per repeating unit.

Even more suitably, the polymeric material is polypropylene of any suitable density. The polypropylene material may have any thickness but preferably has a thickness of greater than 2 or 5 micron or suitably greater than 20 micron, and even more suitably in the range of 70 to 120 micron, and ideally in the range of 90 to 100 micron.

In an embodiment, the side of the membrane having the coating has a porosity in the range of 5 to 95%, suitably 30 to 70%, even more suitably 40 to 60%, and still even more suitably is approximately 50%±3%. The term porosity is a ratio of the area of pores in the face of the substrate to the area of the face of the substrate.

The pore size of the substrate is dependent on the manufacturing process of the substrate and can be of any size up to 100 micron or greater. However, according to an embodiment, the size of individual pores may have cross section of up to 40 micron, suitably up to 20 micron in cross-section, and even more suitably up to 5 micron and even still more suitably in the range of 0.1 to 2 micron.

The hydrophobicity of the coating may be attributable to at least two characteristics, namely chemical composition and surface roughness which may be measured in the form of a range of different parameters.

The hydrophobicity of the coated surface may be characterised in terms of wetting energy or contact angle. In an embodiment, the membrane has a contact angle with water of at least 129 degrees, and suitably greater than 135, even more suitably greater than 140 degrees and still even more suitably 150±1.1 degrees.

Although the hydrophobic coating opposes or substantially resists the liquid solvent from penetrating or entering the pores of the substrate, it is possible that a relatively small amount of the liquid solvent wets the pores. Pore wetting can be calculated by weighting the inverse of diffusivity values for carbon dioxide through the gas and liquid phases to provide an equivalent membrane mass transfer resistance to that experimentally determined. In an embodiment, pore wetting by the liquid solvent is suitably kept below 2.34%, and even more suitably less than 1.0% and ideally is less that 0.5%.

The pore size and hydrophobicity of the membrane is also represented in the breakthrough pressure of the membrane. The breakthrough pressure being the measure of the pressure required to force the liquid solvent through the membrane from the solvent side to the gas phase side. In the situation in which the substrate is polypropylene and the coating is a fluorinated coating, suitably, the breakthrough pressure of the membrane using an iospropanol solution is in the range of 50 to 90 kPa gauge, and even more suitably in the range of 60 to 80 kPa.

The roughness of the coating may be measured in terms of a root mean square of the roughness. We have found that a root means square of at least 200 nm and suitably in the range of 400 to 600 nm can beneficially contribute to hydrophobicity.

The coating may be any substantially inert coating.

The hydrophobicity of the coating may in part be attributable to the chemistry of the coating. When the substrate is an organic based material, the coating may be an oxygenated, nitrogenated, chlorinated or siliconated coating that is applied to the substrate.

Suitably, the coating is a fluorine coating or fluorine rich coating that forms a covalent bond to the substrate. For example, the coating may be formed from any fluoride and may be formed from physical vapour deposition of fluorine from a fluoride containing material including sodium or silicon fluorides, organofluorides or fluorocarbons such as, but by no means limited to, polytetrafluoroethylene (Teflon™) or tetrafluoromethane.

In an embodiment, the fluorine to carbon ratio of the coating based on the C1s spectra analysis is in the range of 1.2 to 1.9 and suitably in the range of 1.5 to 1.7.

In an embodiment, the gas separating membrane may have a flat conformation or a hollow fibre conformation in which the coating is applied to either inside or outside surfaces of the tubular conformation, but suitably to both the inside and outside surfaces. The hollow fibre conformation provides greater surface area per volume than the flat structure and when in use, suitably the gas phase contacts the outside surface of the hollow fibre conformation and the liquid solvent is conveyed through an internal lumen.

In an embodiment, the coating opposes or resists the liquid solvent from penetrating and wetting the pores up to a level of 1% when determined by weighting the inverse of diffusivity values for carbon dioxide through the gas and liquid phases.

The present invention may also be said to reside in the use of the resin including any one or combination of the features described above in absorbing carbon dioxide from a flue gas stream including a flue gas stream of the fossil fuelled power station.

It may be said that the present invention resides in a method of manufacturing a gas absorption membrane for separating carbon dioxide from other gas species, the method including the steps of:

a) locating a thin film substrate having micro-pores that extend through the substrate in a physical vapour deposition chamber;

b) locating a targeted material into the chamber; and

c) generating a plasma in the chamber so as to deposit or sputter a thin coating of the targeted material onto at least one side of the substrate without substantially obstructing the pores of the substrate.

One of the benefits of the membrane of the present invention is that the gas phase containing carbon dioxide can be conveyed through the pores of the membrane while a desired liquid solvent is substantially prevented from penetrating the pores so as to form an interface at which carbon dioxide can be transferred from the gas phase to the liquid solvent.

It may also be said that the present invention resides in a method of manufacturing a membrane that facilitates the mass transfer of a targeted substance, the method including the steps of:

a) locating a thin film substrate having micro-pores that extend through the substrate in a physical vapour deposition chamber;

b) locating a material on an electrode on the chamber to be sputtered onto the substrate; and

c) generating a plasma in the chamber so as to deposit or sputter a thin coating of the material onto at least one side of the substrate without substantially obstructing the pores of the substrate, wherein the coating is hydrophobic.

The method of manufacture of the membrane may also include any one or a combination of the features of the gas absorption membrane described above including any preferred features.

### EXAMPLES

The present invention will now be described with reference to the following non-limiting examples.

### Example 1

This example involves a flat substrate of polypropylene being plasma treated to form a fluorinated coating which is hereinafter referred to as the treated polypropylene membrane or PTPP. The PTPP is manufactured and compared for mass transfer performance with untreated polypropylene (PP) and polytetrafluoroethylene (PTFE).

Scanning electron microscopy (SEM) images of the membranes were captured and the surface morphology analysed to calculate surface porosity, average pore size and thickness. An image analysis program, namely Version 1.24 by ImageJ was used to calculate the surface porosity. A summary of the properties of the PP, PTPP and PTFE membranes is provided in Table 1 below.

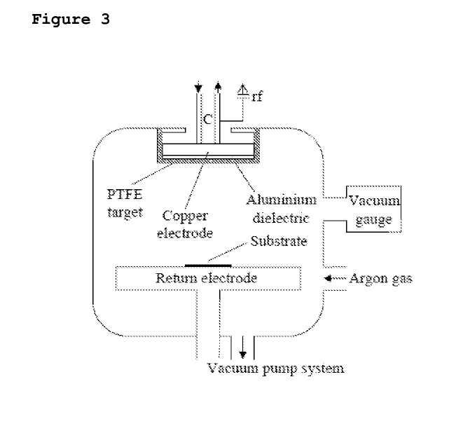

A sample of the PP membrane was plasma treated to form a fluorinated coating on one side of the PP. The apparatus and method for treating the PP membrane is schematically illustrated in FIG. 3. The apparatus includes a reaction chamber that is capacitatively coupled to a radio-frequency generator (Advanced Energy, Model RFX600, CO USA) which features a 600 W maximum power output delivered into a 50 ohm load via an auto-matching network (Advanced Energy, Model ATX600, CO USA). A vacuum system consisting of a backing pump (BOC Edwards, Rotary Pump Model E2M12, UK), a stainless steel liquid nitrogen trap (MDC Vacuum Products, Model 434005, CA USA) to trap condensable vapours, and a high vacuum pump (Pfeiffer Turbomolecular Pump, Model TPH 330 S, UK) that reaches pressures as low as 10⁻⁵ Torr are connected to the chamber. The absolute pressure in the chamber was measured by a wide range gauge (BOC Edwards, Model WRG-S-NW25, UK) which features both Pirani and magnetron gauge elements in the reaction chamber and three pirani gauges (BOC Edwards, UK) were used to monitor the pressure of the pumping system.

A needle valve was used to supply argon gas into the bottom of the reaction chamber and finally, a radio-frequency (13.56 MHz) generator reactor was used to created the require plasma.

As can be seen in FIG. 3, a block of PTFE was attached to a copper electrode and a sample of the PP membrane substrate was placed on a circular stage approximately 15 cm below the PTFE block which covers the active electrode, and serves as a target for sputtering.

In order to sputter coat the PP membrane samples, the following operating procedure was carried out. The samples were placed on the return electrode and a vacuum was generated in the reaction chamber by initially using the backing pump and liquid nitrogen trap and then activating the high pressure pump. Once an adequate base pressure had been reached, ultra high purity argon gas (BOC Gases Ltd., >99.999% purity, Australia) was administered to the reaction chamber at 5 cm³/min using a high precision needle valve before plasma was sparked using the radio-frequency generator. A power of 200 W was administered for 30 minutes during which a thin coating of fluoride was applied to the substrate. Subsequently, the chamber was brought to atmospheric pressure and the samples could be removed.

A summary of the porosity, average pore size and thickness data for the PP, PTFE and PTPP membranes is provided in Table 1.

TABLE 1

| | Membrane | | |
|---|---|---|---|
| | | | Plasma |
| | PP | PTFE | Treated PP |
| Manufacturer | Membrana Accurel | Sartorius | — |
| | (Germany) | (Germany) | |
| Porosity (%) | 61 ± 1.2 | 26 ± 4.9 | 51 ± 2.8 |
| Average Pore Size | 0.50 ± 0.11 | 0.49 ± 0.18 | 0.30 ± 0.03 |
| (μm) | | | |
| Thickness (μm) | 93 ± 2.1 | 65* | 93 ± 1.9 |

*Specified by the manufacturer.

Chemical Composition

X-ray photoelectron spectroscopy (XPS) was used in order to characterize the chemical composition of the PP and PTPP membranes. XPS was performed using an Axis Ultra spectrometer (Kratos Analytical, UK) equipped with a monochromatised X-ray source operating at 150 W. XPS has a 2-10 nm sampling depth, a detection limit of 0.5% and an error limit of ±10% relative to the percentage quantity of each element detected on the surface. The XPS spectra of the carbon 1s orbital for both PP untreated and the treated PTPP shows that the treated surface was highly fluorinated. There is a large change in the C1s envelope going from untreated to treated PP, which can be attributed to the formation of fluorinated carbon centres C—F at 288.0 eV, C—F₂ at 290.0 eV and C—F₃ at 292.0 eV.

The fluorine to carbon ratio for plasma treated PP was calculated by deconvolution of the regional C1s spectra and estimated as being approximately 1.61. The fluorine to carbon ratio for pristine PTFE is 2.0. This shows that PTFE sputtering is capable of achieving similarly fluorinated surfaces to PTFE. Depending on the various factors it is expected that useful levels of fluorination include fluorine to carbon ratios in the range from 1.2 to 1.9.

Together with surface roughness, the hydrophobocity of the PTPP membrane is a function of the chemistry of the coating. In the case of this example, the hydrophobicity of the coating is achieved by the level of fluorination. A measure of the hydrophobicity may be the surface tension or contact angle.

Contact Angle

A contact angle goniometer (equipped with FTÅ200 analysis software) was used to measure the contact angle of both distilled water and 20 wt % MEA solution on flat sheet membranes. Water contact angles were tested on PP, PTFE and PTPP, both fresh and after exposure to a 20 wt % MEA solution for 25 days. The same instrument was used to determine the surface tension of the MEA solutions in air. The results are shown in Table 2 below.

Breakthrough Pressure

Breakthrough pressure measurements were conducted to find the liquid entry pressure of the membranes by pressuring a solution of 20 wt % isopropanol (Sigma Aldrich, Australia) which has a surface tension of 34 mN/m on supported porous flat sheet membranes using nitrogen gas. A digital pressure gauge was used to monitor the step-wise increase in gas pressure by 1 kPa/minute. Breakthrough of the solution was visually observed and averages of 10 measurements were calculated per membrane type to allow for variability between membrane sheets.

Table 2 below provides a summary of measurable properties of the membranes that reflect the hydrophobicity of the PTPP membrane.

TABLE 2

| | Polymer Type | | |
|---|---|---|---|
| | | | Plasma |
| | PP | PTFE | Treated PP |
| Water contact angle | 127 ± 1.9 | 139 ± 3.6 | 151 ± 1.1 |
| 20 wt % MEA contact angle | 117 ± 4 | 132 ± 2 | 138 ± 2 |
| Water contact angle after MEA | 110 ± 5.0 | 138 ± 3 | 149 ± 3.3 |
| exposure | | | |
| Breakthrough pressure (kPa) | 29 ± 1.9 | 91 ± 8.3 | 71 ± 6.4 |
| Surface tension of liquid mixture | 54 | 44 | 43 |
| which has a contact angle of 90° | | | |
| on a membrane surface | | | |
| (γL⁹⁰) (mN/m) | | | |

FIG. 5 shows the relationship between wetting energy and surface tension for each of the membranes. A wetting energy below zero indicates that the surface is not being wet. For a wetting energy above zero, the surface is being spontaneously wet by the solvent. For very high concentrations of MEA, the PP membrane is spontaneously wet while the PTFE and PTPP membranes do not become wet. In the MEA concentration range of interest (10-30 wt %), the PTPP membrane displays the most ideal wetting behaviour, followed by the PTFE and PP membrane materials.

Roughness

The surface roughness of the PTPP was assessed using an atomic force microscope (AFM) images. Atomic force microscopy (AFM) images were taken on air dried films with a Nanoscope IIIa microscope (Digital Instruments Inc., Santa Barbara, Calif.) in tapping mode using silicon cantilevers with a resonance frequency of constant amplitude of 290 kHz (MikroMasch, USA). Several images were taken on macroscopically separated areas of the films to ensure representative AFM images of the samples. Image processing (first-order flattening and plane fitting) was carried out with Nanoscope 4.43r8 software. AFM was used to find the root mean square roughness (Rₘₛ) of the membranes to gauge the extent of their surface roughness. The surface roughness contributes to the hydrophobicity of the membrane. The measurements conducted show the coating on the PTPP has an average root mean square roughness of approximately 456 nm compared to a surface roughness of 149 nm for the untreated PP. Moreover, a root mean square roughness of at least 200 nm and suitably in the range of 300 to 600 nm could well have an impact on the hydrophobicity of the PTPP.

Surface Morphology

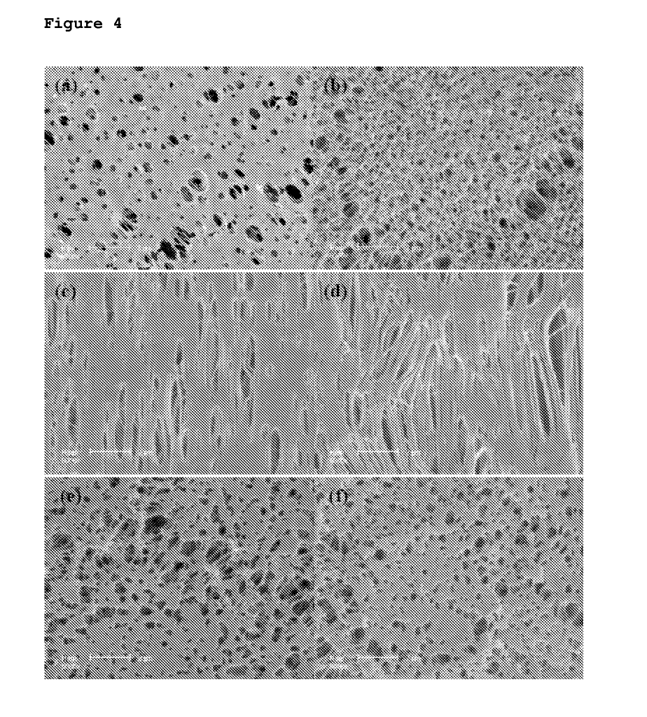

FIGS. 4a to 4f is a series of SEM photographs of the control PP, PTFE and PTPP membranes. The photographs provide a good comparison of the surface morphology of the fresh membrane surfaces in FIGS. 4a, 4c and 4e, and surface morphology after exposure to 20 wt % MEA for 25 days in FIGS. 4b, 4d and 4f.

In particular, FIGS. 4a and 4b are of the PP membrane and the photos show that the PP surface morphology changed when exposed to MEA with enlarged and disrupted pores and a lower surface porosity (which drops from 61% to 52%). A change in the PTFE membrane surface morphology is less but also evident, see FIGS. 4c and 4d. However, the pore size of the PTFE appears to be marginally enlarged and the membrane may have shrunk. However, little change in the morphology of the PTPP membrane occurred, see FIGS. 4e and 4f.

A visual comparison between FIGS. 4a and 4e also shows that the coating does not obstruct the pores of the substrate.

CO₂ Mass Transfer Performance

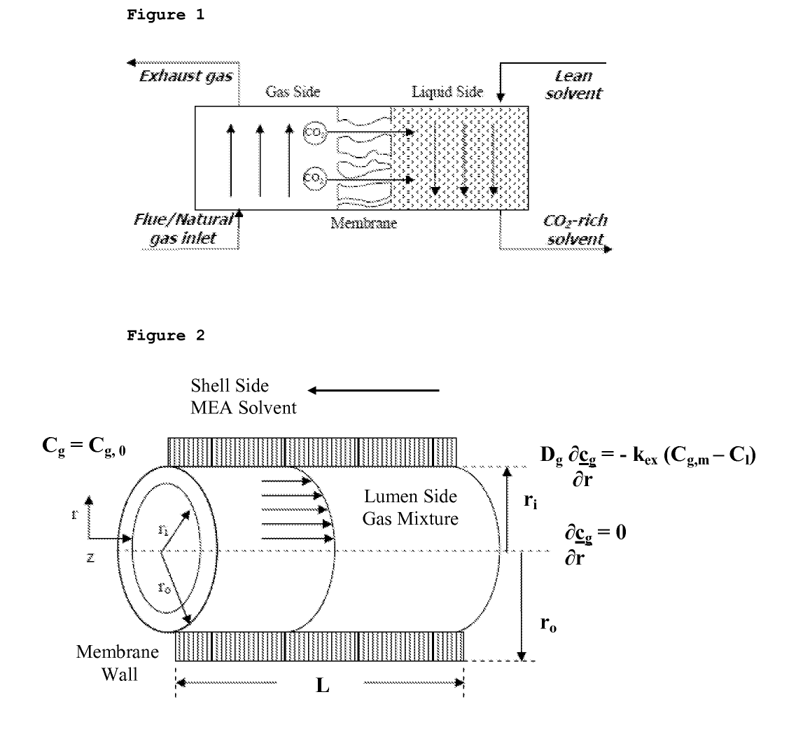

FIG. 1 is a schematic cross-section of the membrane when in use for transferring carbon dioxide from the gas phase to the liquid solvent. As can be seen, the gas phase such as flue gas is conveyed on one side of the membrane and penetrates the micro-pores of the membrane. The hydrophobic fluorine coating, not shown in FIG. 1, faces the liquid solvent. The purpose of the coating is to preserve the membrane substrate from chemical attack of the liquid solvent and substantially resist or oppose the liquid solvent from entering the pores. Liquid solvent in the pores has a detrimental effect on the overall mass transfer of carbon dioxide to the liquid solvent.

The mass transfer performance of PP, PTFE and PTPP membranes were tested using an apparatus. The apparatus comprised the membrane being tested being secured between 2 silicon o-rings seals and supported on low pressure on the gas side of the membrane. The support left an exposed membrane area of 7.26 cm³. Pressure transducers such as those available from Davidson Measurement Pty Ltd were then used to monitor the transmembrane pressure difference.

The CO₂ gas phase concentration was measured using a Shimadzu 8A GC with a thermal conductivity detector, using helium carrier gas and a Poropak-Q packed column. CO₂ liquid loading and MEA concentration were measured using a Chittick Carbon Dioxide Analyser (VWR International, AB, Canada) according to the procedure outlined by the Association of Official Analytical Chemists. A known volume of loaded MEA was placed into a volumetric flask with methyl orange indicator and connected to the gastight titration apparatus. 1 M HCl (supplied by Sigma Aldrich, Australia) was administered to the flask to free bound CO₂ from the solution. A calibrated metering tube filled with standard solution was displaced by the freed CO₂ and which could be used to back-calculate the CO₂ loading of the MEA. For a typical absorption experiment, the gas and liquid chamber stirrer speeds were adjusted and data acquisition commenced. The liquid flow was started first at a constant flow rate of approximately 70 mL/min followed by the gas which flowed co-currently to the liquid at 0.3 L/min. A ball valve was adjusted to increase the liquid pressure to approximately 0.1 bar higher than the gas phase pressure. The CO₂ gas phase concentrations at equilibrium at the membrane cell inlet and outlet were measured and used to calculate the overall mass transfer coefficient. Liquid samples from the inlet and outlet of the membrane cell were analysed to determine their CO₂ loading which was used to complete a mass balance for CO₂ across the membrane unit and verify the precision of each experiment. Due to the relatively small amount of CO₂ absorption into the liquid, a tolerance of ±30% error for the mass balance was employed. The CO₂ mass transfer rate was averaged from 10 experimental results to account for the small membrane area available for gas-liquid contact and the large differences in morphology that were encountered between membrane discs (despite all membranes originating from a single batch).

The overall mass transfer coefficient K can be calculated as:

$$K = \frac{{Q}_{g , i n} {C}_{g , i n} - {Q}_{g , out} {C}_{g , out}}{A {C}_{g , out}}$$

Where Q_{g,in} and Q_{g,out} are the volumetric flow rates of CO₂ entering or exiting the membrane unit in the gas phase, C_{g,in} and C_{g,out} are the concentrations of CO₂ entering and exiting the membrane unit in the gas phase and A is the mass transfer area.

In order to determine whether the performance of each of the three membranes degrades with MEA exposure time, absorption experiments were conducted with fresh membranes and then with membranes that had been pre-soaked for 25 days. Membranes were pre-soaked by floating them on a solution of 20 wt % MEA under atmospheric conditions.

Table 3 below provides a comparison of membrane absorption performance. The PTPP membrane has a mass transfer rate approximately 70% higher than the PP membrane and 40% higher than the PTFE membrane which is reflected in the contact angles shown in Table 2.

TABLE 3

| | | Mass Transfer Coefficient for |
|---|---|---|
| | Mass Transfer Coefficient for | Pre-Soaked |
| Membrane | Fresh Membranes (m/s) × 10⁴ | Membranes (m/s) × 10⁴ |
| PP | 1.01 ± 0.33 | 0.70 ± 0.16 |
| PTFE | 1.80 ± 0.30 | 1.47 ± 0.37 |
| PT PP | 3.18 ± 0.21 | 2.56 ± 0.46 |

As can be seen in Table 3, all membranes experienced a drop in performance after MEA exposure. The overall mass transfer coefficients using PTFE, plasma treated PT PP and PP membrane drop by approximately 18, 20 and 30% respectively after 25 days of solvent exposure. With the exception of the PTPP membrane, this drop in absorption performance is supported by SEM images which show extensive fibre degradation after MEA exposure which can be seen in FIGS. 4a to 4f.

The mass transfer coefficient for a fully wetted PP membrane ((1.4±0.3)×10⁻⁵ m/s) was also measured by forcefully filtering the solvent through the membrane prior to the absorption experiment. For the wetted membrane, the overall mass transfer coefficient does not vary with liquid flow rate which confirms that the membrane resistance is dominant.

The porosity of the membranes shown in Table 1 differ significantly and will have an impact on the mass transfer coefficients in Table 3 above. Generally speaking a reduction in porosity is equivalent to a reduction in mass transfer area. However, a comparison of the membrane performance based on the membrane void area can give a direct measure of the membrane wettability. Table 4 below compares the performance of the four membrane types using an effective overall mass transfer coefficient (K_{eff}) which is based on the effective membrane area. Using a standardised void fraction, the PTFE membrane performs at the highest level and PP is clearly the lowest performing membrane.

TABLE 4

| | Effective Mass Transfer | Effective Mass Transfer |
|---|---|---|
| | Coefficient for Fresh | Coefficient for Pre-Soaked |
| Membrane | Membranes (m/s) × 10⁴ | Membranes (m/s) × 10⁴ |
| PP | 1.64 ± 0.33 | 1.14 ± 0.16 |
| PTFE | 6.85 ± 0.30 | 5.61 ± 0.37 |
| PT PP | 6.18 ± 0.21 | 4.97 ± 0.46 |

Using empirical correlations it is possible to estimate the resistance to mass transfer attributable to the gas film and liquid film resistances. Subtraction of these resistances from the inverse of the overall mass transfer coefficient allows calculation of the membrane resistance. Table 5 below provides a break down of the mass transfer resistances attributable to PP, PTPP and PTFE before exposure, after 25 days exposure and when fully wet with MEA solution.

TABLE 5

| Mem- | | | | | | | |
|---|---|---|---|---|---|---|---|
| brane | | | | | Contribution to Overall | | |
| (Days | | | | | Resistance (%) | | |
| of MEA | Resistances (s/m) | | | | | | Mem- |
| Expo- | | Liq- | | Mem- | Liquid | Gas | brane |
| sure) | Overall | uid | Gas | brane | O̅v̅e̅r̅a̅l̅l̅ | O̅v̅e̅r̅a̅l̅l̅ | O̅v̅e̅r̅a̅l̅l̅ |
| PP (0) | 6084 | 356 | 76 | 5652 | 5.9 | 1.2 | 92.9 |
| PTFE | 1459 | 356 | 76 | 1027 | 24.4 | 5.2 | 70.4 |
| (0) | | | | | | | |
| PT PP | 1618 | 356 | 76 | 1186 | 12.0 | 4.7 | 73.3 |
| (0) | | | | | | | |
| PP (25) | 8753 | 356 | 76 | 8322 | 4.1 | 0.9 | 95.1 |
| PTFE | 1783 | 356 | 76 | 1351 | 20.0 | 4.2 | 75.8 |
| (25) | | | | | | | |
| PT PP | 2011 | 356 | 76 | 1580 | 17.7 | 3.8 | 78.5 |
| (25) | | | | | | | |
| PP | 70934 | 356 | 76 | 70502 | 0.5 | 0.1 | 99.4 |
| (fully | | | | | | | |
| wetted) | | | | | | | |

Average diffusion coefficients were calculated from the membrane resistance and from these values, the portion of pores that were wetted was estimated by weighting the inverse of the diffusivity values for CO₂ through the gas and liquid phases using a pore wetting factor or proportion. Table 6 below provides a summary of the results.

TABLE 6

| | Membrane mass | | |
|---|---|---|---|
| | transfer | Average Diffusion | Pore |
| | coefficient, kₘ × | Coefficient × 10⁷ | Wetting |
| Membrane | 10⁴ (m/s) | (m²/s) | (%) |
| PP - fresh | 1.77 | 0.84 | 2.34 |
| PTFE - fresh | 9.73 | 9.17 | 0.15 |
| PT PP - fresh | 8.43 | 6.53 | 0.26 |
| PP - pre-soaked | 1.20 | 0.58 | 3.45 |
| PTFE - pre-soaked | 7.40 | 6.97 | 0.23 |
| PT PP - pre-soaked | 6.33 | 4.90 | 0.36 |
| PP - fully wetted | 0.14 | 0.07 | 29.46 |

As expected, the pores of the PTFE membrane were wet the least, followed by the PTPP and the untreated PP membrane. In terms of wettability, the PTPP membrane is at least comparable to PTFE but is clearly superior to the untreated PP membrane. It can be seen from table 6 above, that even a small degree of pore wetting results in a significant reduction in the mass transfer coefficient of the membrane. It is recommended that pore wetting be kept below 2.34% and suitably less than 1.0% and even more suitably less that 0.5%.

### Example 2

The procedure as outline above was again repeated in respect of the hollow tubular or hollow fibre PP membranes that provided “a control”, PTFE hollow fibres that represent that ideal situation and plasma treated polypropylene or PTPP hollow fibres that are the subject of the present invention. FIG. 2 is a representation of a single hollow fibre. Again a scanning electron microscope (SEM) and X-ray photoelectron spectroscopy (XPS) was conducted to determine physical properties and composition of the membranes.

Table 7 below is a summary of the physical properties of the membranes.

TABLE 7

| | Polymer Type | | |
|---|---|---|---|
| | PP | PTFE | Plasma Treated PP |
| Fibre Manufacturer | Memtec, | Sumitomo | Memtec, Australia |
| | Australia | Electric | (treated in house) |
| | | Fine Polymer, | |
| | | Japan | |
| Fibre ID/OD (mm) | 0.3/0.67 | 1/2 | 0.3/0.67 |
| No. of fibres | 500 | 27 | 500 |
| Contactor Length (cm) | 12.7 | 11.0 | 12.7 |
| Mass Transfer Area, | 598/1337 | 93/187 | 598/1337 |
| based on ID/OD (cm²) | | | |
| Membrane contactor | 71 | 86 | 71 |
| void fraction (%) | | | |

A series of hollow fibre membrane cartridges were constructed in accordance with the specifications listed in Table 7 and tested in a counter current flow membrane module.

The outside and inside surfaces of the hollow fibres were sputter treated in accordance with the technique described under Example 1. In essence the sputter technique forms an ultra-thin fluorinated hydrophobic surface that substantially retains the micro-porous structure of the underlying membrane.

Cartridge assemblies of the tubular membranes were exposed to MEA in absorption trials by which either the gas phase containing carbon dioxide or MEA solvent was conveyed through the lumen. The absorption trial was conducted as follows, industrial grade CO₂ (Praxair, >99.9% purity, Canada) was mixed with air in the proportion 14:86 by volume to simulate a flue gas stream. Gas flow controllers (Aalborg, Model GFC-17A, NY USA) were used to regulate the gas flows before they entered a pipe mixer and filter. Analytical grade MEA (Fisher Scientific, USA) was diluted with deionised water to 10-30 wt % and preloaded to 0.27-0.30 mol CO₂/mol MEA by bubbling CO₂ through the solution using a sintered glass sparger before use to simulate use of a regenerated solution. A magnetic drive gear pump (Cole Parmer, IL USA) pumped MEA solution through a liquid filter and rotameter before being passed through the membrane contactor. The liquid passed through a liquid trap before entering the outlet tank to create a positive liquid head and prevent gas entrainment. Analogue pressure readings were available for the differential pressure across both the gas and liquid phases and also for the liquid inlet and outlet (Ashcroft, Conn., USA). The CO₂ gas phase concentration was measured using an on-line infra-red gas analyser from Nova Analytical Systems Inc. (Hamilton, Model 302WP, ON Canada).

For a typical absorption experiment, the gas flow was started first (1 L/min CO₂ and 6.1 L/min air). After consistency in the CO₂ concentration at the contactor inlet and outlet was obtained, the liquid flow was started (18-85 mL/min). The outlet liquid pressure was approximately 0.1 bar higher than the gas phase inlet pressure to prevent gas bubbling through the liquid. The liquid flow rate was measured at the outlet using a measuring cylinder. The CO₂ gas phase concentrations at equilibrium at the contactor inlet, outlet and (for shell side gas flow) mid-point were measured and used to calculate the overall mass transfer coefficient. Liquid CO₂ loading was also measured to complete a mass balance for CO₂ absorption across the hollow fibre unit to verify the quality of each experiment.

The CO₂ flux (N) through the membrane contactor is given by:

$$N = \frac{( {Y}_{i n} - {Y}_{out} ) G}{A}$$

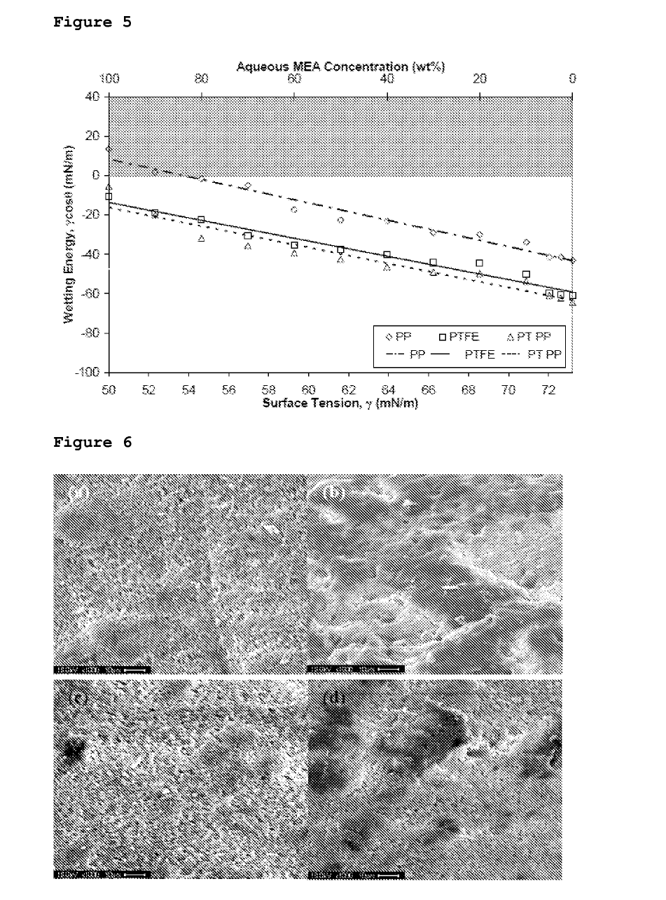

FIGS. 6a and 6b are SEM photos of the outside of an untreated PP membrane before exposure to MEA and after exposure to MEA. FIGS. 6c and 6d are SEM photos of the outside of a plasma treated PTPP membrane before exposure to MEA and after exposure to MEA. The photos were taken at a magnification of 1000×.

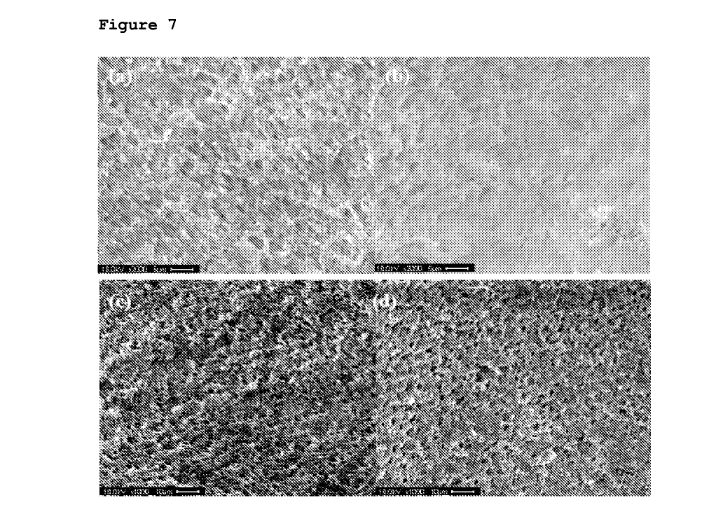

FIGS. 7a and 7c are SEM photos of the inside of an untreated PP membrane before exposure to MEA and after exposure to MEA. FIGS. 7c and 7d are SEM photos of the inside of a plasma treated PTPP membrane before exposure to MEA and after exposure to MEA. The photos were taken at a magnification of 2000×.

The photos of FIGS. 6a, 6b, 7a and 7b show the outside membrane surface undergoes more morphologicial degradation on contact with MEA solvent while the inside surface is relatively unchanged. Furthermore, an XPS analysis of the outside and inside surfaces of the untreated PP and PTPP indicate that the inside surface has lower levels of oxygen and slightly higher levels of fluorine compared to the outside. Table 8 below is a summary of an XPS analysis of outside and inside surfaces of untreated PP and PTPP before and after exposure to MEA solution.

TABLE 8

| | Mass Concentration (%) | | | |
|---|---|---|---|---|
| Membrane Surface | Fluorine | Oxygen | Nitrogen | Carbon |
| Fresh Untreated PP - | 0 | 9.7 ± 1 | 1.6 ± 0.2 | 89 ± 9 |
| outside | | | | |
| Fresh PT PP - outside | 2.0 ± 0.2 | 16 ± 2 | 2.0 ± 0.2 | 80 ± 8 |
| Fresh Untreated PP - | 0 | 0.8 ± 0.08 | 0 | 99 ± 10 |
| inside | | | | |
| Used Untreated PP - | 0 | 1.5 ± 0.2 | 0 | 99 ± 10 |
| inside | | | | |
| Fresh PT PP - inside | 2.4 ± 0.2 | 10 ± 1 | 2.2 ± 0.2 | 85 ± 9 |
| Used PT PP - inside | 2.3 ± 0.2 | 8 ± 0.8 | 0 | 90 ± 9 |

CO₂ Absorption with the Gas Flow in the Lumen

A direct comparison of untreated PP membrane to PTPP is possible since the cartridges have the same mass transfer area; approximately 1337 cm² based on the fibre outer diameter (Table 1). The performance of the PP membrane cartridges were first tested with liquid flow through the contactor shell. The untreated PP performs at a higher level than the plasma treated membrane. Relative to the inside surface, the outside surface of the plasma treated PP fibres were coated less effectively with fluorine which makes this surface less inert and susceptible to wetting and degradation by MEA. This trend is maintained when the MEA concentration is varied and over longer periods of absorption. Over 165 hours of absorption, the untreated and plasma treated PP cartridge performance drop by an average of 19% and 12% respectively using 20 wt % MEA flowing at 17-83 mL/min through the contactor shell.

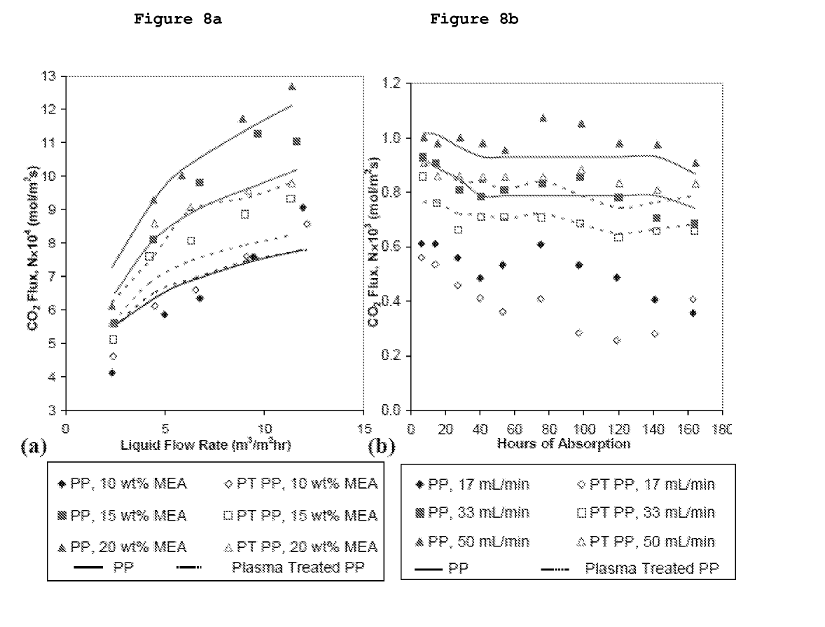

In particular FIG. 8a illustrates changes in CO₂ flux for PP and PTPP membranes cartridges with liquid flow on the outside of the tubes (shell side) and gas flowing in the tube lumens at various concentrations from 10 wt % to 20 wt %. FIG. 8b illustrates changes in flux for PP and PTPP membranes form the same configuration with a 20 wt % MEA solution and at various flowrates as shown.

After 165 hours of absorption, the wetting is predicted to increase from 0.4% to 0.7% for the untreated PP membrane cartridge and from 0.65% to 0.85% for the treated PP membrane cartridge. The modelled CO₂ absorption flux is not shown for the lowest flow rate in FIG. 7b because either the modelled predictions or experimental data is less accurate for lower liquid flow rates.

A relatively small degree of wetting causes a large drop in the CO₂ mass transfer rate. Although only 0.7% of the membrane pores are predicted to be wetted after 165 hours of contact with 20 wt % MEA, the experimentally determined CO₂ flux is 2 times smaller than the theoretically predicted flux through non-wetted pores. Furthermore, the effect of pore wetting is amplified as the liquid flow rate increases. This is because the liquid resistance decreases with increasing liquid flow rate which results in the membrane resistance contributing a larger proportion of the total resistance to mass transfer.

CO₂ Adsorption with Gas Flow in Shell

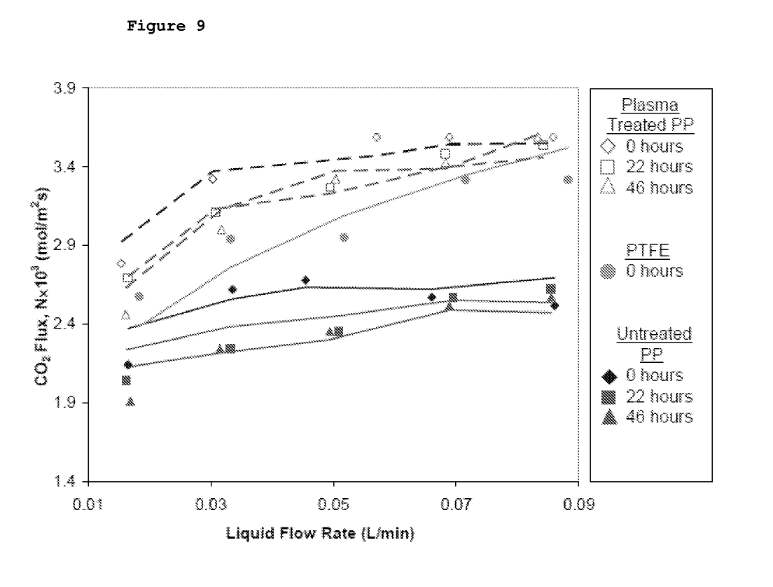

FIG. 9 provides test results in which the MEA solution is conveyed through the lumen of the hollow fibres and the gas on the outside of the hollow fibres. The comparison shown in FIG. 9 is for a CO₂ flux using 20 wt % MEA solution after 0 hours, 22 hours and 46 hours while the PTFE was only tested once based on its compatibility with MEA.

The untreated PP has the lowest flux, whereas the PTPP has a flux greater than that of PFTE. The better efficiency in the PTPP over PFTE we believe is attributable to the PTPP has having increased roughness over the PFTE membranes. A similar comparison is also evident in FIG. 5 of the flat sheet Example 1.

Modelling indicates that for untreated PP, the pore wetting percentage increases to 0.6% while the plasma treated PP fibres are predicted to be only 0.2% wetted following 46 hours of absorption with 20 wt % MEA. The PTFE fibres are predicted to have a similar degree of wetting (0.25%) to the plasma treated PP fibres. The plasma treated PP provides the highest flux and maintains a superior performance over the PTFE.

The hollow fibres and flat PTPP conformations described in examples 1 and 2 above are expected to have a useable life of up to 2 or 3 years.

1. A gas absorption membrane for separating carbon dioxide from a gas phase, the membrane comprising:
a) a substrate having micro-pores that extend through the substrate; and
b) a thin hydrophobic coating on one side of the substrate in which the pores of the substrate are substantially unobstructed by the coating so that the gas phase can penetrate the pores, and the coating opposes or substantially resists a liquid solvent for absorbing carbon dioxide, from penetrating the pores of the membrane from the side having the coating.

2. A gas absorption membrane for separating carbon dioxide in a gas phase such as a flue gas of a coal fired power station, the membrane comprising:
a) a substrate having micro-pores that extend through the substrate to allow the gas phase to penetrate into the substrate; and
b) a thin coating on at least one side of the substrate such that the pores are substantially unobstructed by the coating, and when in use, the gas phase penetrates the pores of the substrate and a liquid solvent in contact with the coating is opposed or resisted from penetrating the pores such that carbon dioxide in the pores of the substrate is transferred to the liquid solvent.

3. The membrane according to claim 2, wherein the coating is a hydrophobic coating that opposes or resists an aqueous solvent from penetrating the pores of the substrate from the side having the coating.

4. The membrane according to claim 2, wherein the substrate is a polymeric material which includes but is by no means limited to thermoplastics and thermoset plastics.

5. The membrane according to claim 2, wherein substrate is a polymeric material including any one or a combination of organic based polymers such as cellulosic acetates, polyacrylates, polyamides, polyesters, polycarbonates, polyimides, polystyrenes and polyolefins.

6. The membrane according to claim 5, wherein the polyolefins having at least two carbon atoms in each repeating unit.

7. The membrane according to claim 2, wherein substrate is polypropylene having a thickness of greater than 2 micron.

8. The membrane according to claim 2, wherein the coating comprises any one or a combination of an oxygenated coating, nitrogenated coating, chlorinated coating, siliconated coating or fluorinated coating.

9. The membrane according to claim 2, wherein the coating is a fluorinated coating or fluorine rich coating that is formed by physical vapour deposition of a fluoride containing material including sodium or silicon fluorides, organofluorides or fluorocarbons such as, but by no means limited to, polytetrafluoroethylene (Teflon™) or tetrafluoromethane.

10. The membrane according to claim 9, wherein the fluorine to carbon ratio of the coating based on the C1s spectra analysis is in the range of 1.2 to 1.9.

11. The membrane according to claim 2, in which the substrate is polypropylene and the coating is a fluorinated coating, and wherein the membrane has a breakthrough pressure ranging of 50 to 90 kPa gauge when using an isopropanol test solution.

12. The membrane according to claim 11, wherein the side of the membrane having the coating has a porosity being a ratio of the area of pores to the total area of the membrane in the range of 5 to 95%.

13. The membrane according to claim 12, wherein membrane has a water contact angle of at least 129 degrees.

14. The membrane according to claim 11, wherein wetting of the micro-pores by the liquid solvent when calculated by weighting the inverse of diffusivity values for carbon dioxide through the gas and liquid phases is less than 1.0%.

15. The membrane according to claim 11, wherein a root means square of the roughness of the coating is in the range of 400 to 600 nm.

16. The membrane according to claim 2, wherein the membrane has a tubular conformation in which the coating is applied to either one or a combination of inside or outside surfaces of the tubular conformation.

17. A gas absorption membrane for separating carbon dioxide from a gas phase, the membrane comprising:
a) a hollow fibre substrate having micro-pores that extend from an internal lumen of the substrate to an outer face of the substrate; and
b) a thin hydrophobic coating on either one or a combination of inner and outer surfaces of the substrate, wherein the pores of the substrate are substantially unobstructed by the coating and when in use, a liquid solvent is conveyed in the lumen of the membrane and the gas phase on the outside of the membrane.

18. The membrane according to claim 17, wherein the coating opposes or resists the liquid solvent from penetrating and wetting the pores.

19. A membrane that can be used in the mass transfer of a targeted substance between a gas phase and an aqueous phase, the membrane comprising:
a) a substrate having micro-pores that extend through the substrate; and
b) a thin hydrophobic coating on one side of the substrate in which the pores of the substrate are substantially unobstructed by the coating so that the gas phase can penetrate the pores, and the coating opposes or substantially resists the aqueous phase from penetrating the pores of the membrane from the side having the coating, and thereby facilitating transfer of the targeted substance between the aqueous and gas phase phases.

20. A method of manufacturing a gas absorption membrane for separating carbon dioxide from other gas species, the method including the steps of:
a) locating a thin film substrate having micro-pores that extend through the substrate in a physical vapour deposition chamber;
b) locating a targeted material in the chamber; and
c) generating a plasma in the chamber so as to deposit or sputter a thin coating of the targeted material onto at least one side of the substrate without substantially obstructing the pores of the substrate.

21. The method according to claim 19, wherein the targeted material is polytetrafluoroethylene.

22. A method of manufacturing a membrane that facilitates the mass transfer of a targeted substance, the method including the steps of:
a) locating a thin film substrate having micro-pores that extend through the substrate in a physical vapour deposition chamber;
b) locating a material on an electrode on the chamber to be sputtered onto the substrate; and
c) generating a plasma in the chamber so as to deposit or sputter a thin coating of the material onto at least one side of the substrate without substantially obstructing the pores of the substrate, wherein the coating is hydrophobic.
